(19) United States
(12) Patent Application Publication
(10) Pub. No.: US 2024/0291471 A1
(43) Pub. Date: Aug. 29, 2024

(54) Frequency Generation in a Quantum Controller

(71) Applicant: Quantum Machines, Tel Aviv (IL)

(72) Inventors: Yonatan Cohen, Tel Aviv (IL); Nissim Ofek, Tel Aviv (IL); Itamar Sivan, Tel Aviv (IL)

(21) Appl. No.: 18/507,503

(22) Filed: Nov. 13, 2023

Related U.S. Application Data
(63) Continuation of application No. 17/853,132, filed on Jun. 29, 2022, now Pat. No. 11,870,443.
Application No. 17/853,132 is a continuation of application No. 17/152,970, filed on Jan. 20, 2021, now Pat. No. 11,387,820.
Application No. 17/152,970 is a continuation of application No. 16/715,633, filed on Dec. 16, 2019, now Pat. No. 10,931,267.
Application No. 16/715,633 is a continuation of application No. 16/527,782, filed on Jul. 31, 2019, now Pat. No. 10,560,076.

(51) Int. Cl. H03K 3/38; G06N 10/00

(52) U.S. Cl. CPC H03K 3/38; G06N 10/00

(57) ABSTRACT

A system comprises time-tracking circuitry and phase parameter generation circuitry. The time-tracking circuitry is operable to generate a time-tracking value corresponding to time elapsed since a reference time. The phase parameter generation circuitry operable to: receive the time-tracking value; receive a control signal that conveys a frequency parameter corresponding to a desired frequency of an oscillating signal; and generate a plurality of phase parameters used for generation of an oscillating signal, wherein the generation of the plurality of phase parameters is based on the time-tracking value and the frequency parameter such that the oscillating signal maintains phase continuity across changes in the frequency parameter.

### PRIORITY CLAIM

This application is a continuation of Ser. No. 16/527,782 filed on Jul. 31, 2019, the entirety of which is hereby incorporated herein by reference.

### BACKGROUND

Limitations and disadvantages of conventional approaches to frequency generation in quantum computer control systems will become apparent to one of skill in the art, through comparison of such approaches with some aspects of the present method and system set forth in the remainder of this disclosure with reference to the drawings.

### BRIEF SUMMARY

Methods and systems are provided for frequency generation in a quantum controller, substantially as illustrated by and/or described in connection with at least one of the figures, as set forth more completely in the claims.

### BRIEF DESCRIPTION OF THE DRAWINGS

FIGS. 1A and 1B compare some aspects of classical (binary) computing and quantum computing.

FIG. 2 shows an example quantum computing system.

FIG. 3A shows an example quantum controller architecture in accordance with various example implementations of this disclosure.

FIG. 3B shows an example implementation of the quantum controller circuitry of FIG. 3A.

FIG. 4 shows an example implementation of the pulser of FIG. 3B.

FIG. 5 shows an example implementation of the pulse operations manager and pulse operations circuitry of FIG. 3B.

FIG. 6A shows frequency generation circuitry of the quantum controller of FIG. 3B.

FIG. 6B shows example components of the control signal IF_{I} of FIG. 6A.

FIGS. 7A and 7B illustrate phase continuity across frequency hops in the frequency generation circuitry of FIGS. 6A and 6B.

FIGS. 8A and 8B illustrate upconversion of a quantum control pulse in an example implementation of this disclosure.

FIG. 9 shows an example configuration of the frequency generation circuitry of FIGS. 6A and 6B to support higher output sample rates.

FIGS. 10A and 10B illustrate upconversion of a quantum control pulse in an example implementation of this disclosure.

FIG. 11 shows another example configuration of the frequency generation circuitry of FIGS. 6A and 6B to support higher output sample rates.

FIG. 12A shows an example frequency generation circuitry operable to generate chirps.

FIG. 12B shows example components of the control signal IF_{I} of FIG. 12A.

### DETAILED DESCRIPTION

Classical computers operate by storing information in the form of binary digits (“bits”) and processing those bits via binary logic gates. At any given time, each bit takes on only one of two discrete values: 0 (or “off”) and 1 (or “on”). The logical operations performed by the binary logic gates are defined by Boolean algebra and circuit behavior is governed by classical physics. In a modern classical system, the circuits for storing the bits and realizing the logical operations are usually made from electrical wires that can carry two different voltages, representing the 0 and 1 of the bit, and transistor-based logic gates that perform the Boolean logic operations.

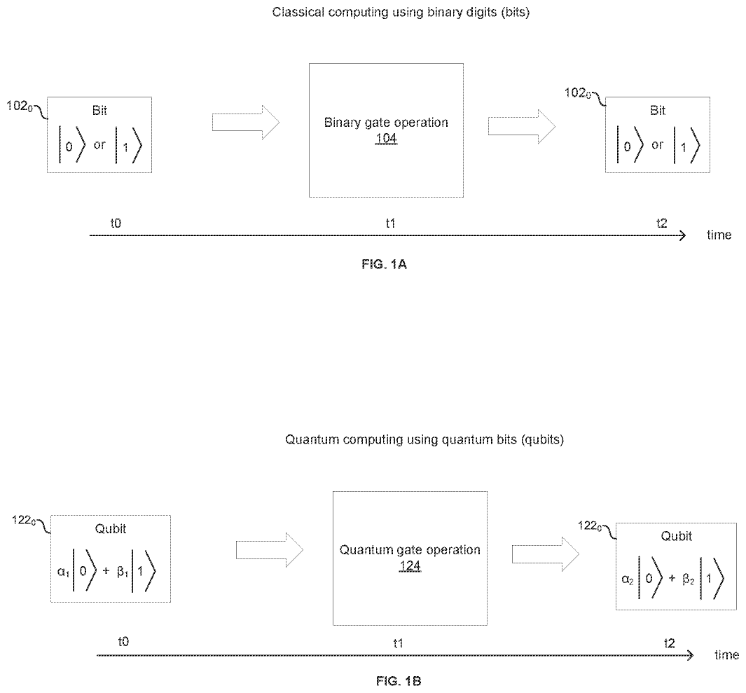

Shown in FIG. 1A is a simple example of a classical computer configured to a bit 102 and apply a single logic operation 104 to the bit 102. At time to the bit 102 is in a first state, at time t1 the logic operation 104 is applied to the bit 102, and at time t2 the bit 102 is in a second state determined by the state at time to and the logic operation. So, for example, the bit 102 may typically be stored as a voltage (e.g., 1 Vdc for a “1” or 0 Vdc for a “0”) which is applied to an input of the logic operation 104 (comprised of one or more transistors). The output of the logic gate is then either 1 Vdc or 0 Vdc, depending on the logic operation performed.

Obviously, a classical computer with a single bit and single logic gate is of limited use, which is why modern classical computers with even modest computation power contain billions of bits and transistors. That is to say, classical computers that can solve increasingly complex problems inevitably require increasingly large numbers of bits and transistors and/or increasingly long amounts of time for carrying out the algorithms. There are, however, some problems which would require an infeasibly large number of transistors and/or infeasibly long amount of time to arrive at a solution. Such problems are referred to as intractable.

Quantum computers operate by storing information in the form of quantum bits (“qubits”) and processing those qubits via quantum gates. Unlike a bit which can only be in one state (either 0 or 1) at any given time, a qubit can be in a superposition of the two states at the same time. More precisely, a quantum bit is a system whose state lives in a two dimensional Hilbert space and is therefore described as a linear combination α|0 [symbol] +β|1 [symbol] , where |0 [symbol] and |1 [symbol] are two basis states, and α and β are complex numbers, usually called probability amplitudes, which satisfy |α|²+|β|²=1. Using this notation, when the qubit is measured, it will be 0 with probability |α|² and will be 1 with probability |β|². |0 [symbol] and | 1 [symbol] can also be represented by two-dimensional basis vectors

$$[ \begin{matrix}1 \\ 0\end{matrix} ] and [ \begin{matrix}0 \\ 1\end{matrix} ] ,$$

respectively, and then the qubit state is represented by

$$[ \begin{matrix}α \\ β\end{matrix} ] .$$

The operations performed by the quantum gates are defined by linear algebra over Hilbert space and circuit behavior is governed by quantum physics. This extra richness in the mathematical behavior of qubits and the operations on them, enables quantum computers to solve some problems much faster than classical computers (in fact some problems that are intractable for classical computers may become trivial for quantum computers).

Shown in FIG. 1B is a simple example of a quantum computer configured to store a qubit 122 and apply a single quantum gate operation 124 to the qubit 122. At time to the qubit 122 is described by α₁|0 [symbol] +β₁|1 [symbol] , at time t1 the logic operation 104 is applied to the qubit 122, and at time t2 the qubits 122 is described by α₂|0 [symbol] +β₂|1 [symbol] .

Unlike a classical bit, a qubit cannot be stored as a single voltage value on a wire. Instead, a qubit is physically realized using a two-level quantum mechanical system. Many physical implementations of qubits have been proposed and developed over the years with some being more promising than others. Some examples of leading qubits implementations include superconducting circuits, spin qubits, and trapped ions.

It is the job of the quantum controller to generate the precise series of external signals, usually pulses of electromagnetic waves and pulses of base band voltage, to perform the desired logic operations (and thus carry out the desired quantum algorithm). Example implementations of a quantum controller are described in further detail below.

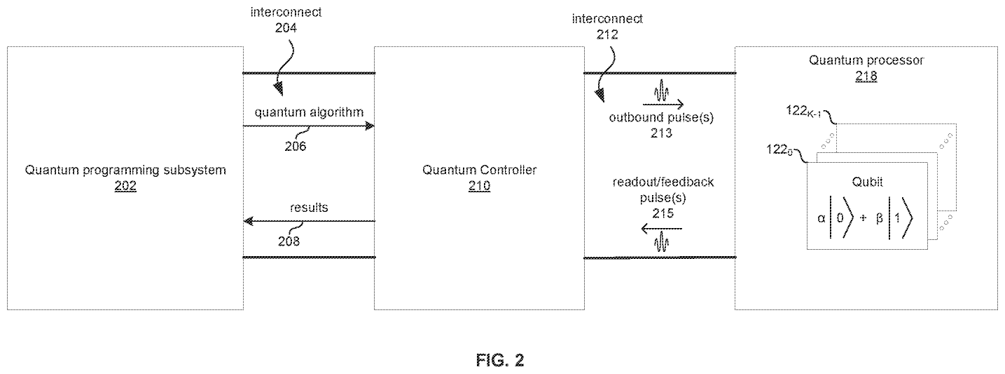

FIG. 2 shows an example quantum computing system. The system comprises a quantum programming subsystem 202, a quantum controller 210, and a quantum processor 218.

The quantum programming subsystem 202 comprises circuitry operable to generate a quantum algorithm description 206 which the quantum controller 210 can execute to carry out the quantum algorithm on the quantum processor 218 (i.e., generate the necessary outbound quantum pulse(s) 213) with little or no human intervention during runtime of the algorithm. In an example implementation, the quantum programming system 202 is a personal computer having installed on it a quantum controller software development kit (SDK) that enables a user to generate the quantum algorithm description 206 using a programming language. In an example implementation, the programming language may be a low-level language which has little or no abstraction from the instruction set used by the specific hardware of the quantum controller 210. Such instructions may be converted to machine code of the quantum controller 210 without need of a compiler or interpreter. In an example implementation, the programming language may be a high-level language which is much more abstracted from the particular hardware of the quantum controller 210. Such instructions may be compiled into machine code before they can be run on the quantum controller 210. In an example implementation the description 206 may be a machine code description of the quantum algorithm. In an example implementation, the description 206 may be a high-level description which the quantum controller 210 may itself compile into machine code. In an example implementation, the description 206 may be a high-level description which the quantum controller 210 may interpret into machine code during runtime. In an example implementation, an operating system or other software layer may run on the quantum controller 210 and the quantum algorithm description 206 may be software instructions that make use of an application programming interface (API) of the software running on the quantum controller 210.

The quantum programming subsystem 202 is coupled to the quantum controller 210 via interconnect 204 which may, for example, utilize universal serial bus (USB), peripheral component interconnect (PCIe) bus, wired or wireless Ethernet, or any other suitable communication protocol.

The quantum controller 210 comprises circuitry operable to load the quantum algorithm description 206 and then perform the quantum algorithm as per the quantum algorithm description 206. In an example implementation, quantum algorithm description 206 is machine code (i.e., series of binary vectors that represent instructions that the quantum controller's hardware can interpret and execute directly) which is loaded into the quantum controller 210. Then, execution of the machine code by the quantum controller 210 causes the quantum controller 210 to generate the necessary outbound quantum control pulse(s) 213 that correspond to the desired operations to be performed on the quantum processor 218 (e.g., sent to qubit(s) for manipulating a state of the qubit(s) or to readout resonator(s) for reading the state of the qubit(s), etc.). Depending on the quantum algorithm to be performed, outbound pulse(s) 213 for carrying out the algorithm may be predetermined at design time and/or may need to be determined during runtime. The runtime determination of the pulses may comprise performance of classical calculations and processing in the quantum controller 210 and/or the quantum programing subsystem 202 during runtime of the algorithm (e.g., runtime analysis of inbound pulses 215 received from the quantum processor 218).

Upon completion of a quantum algorithm and/or during a runtime of a quantum algorithm by the quantum controller 210, the quantum controller 210 may output data/results 208 to the quantum programming subsystem 202. In an example implementation these results may be used to generate a new quantum algorithm description 206 for a subsequent run of the quantum algorithm and/or update the quantum algorithm description during runtime.

The quantum controller 210 is coupled to the quantum processor 218 via interconnect 212 which may comprise, for example, one or more conductors and/or optical fibers.

The quantum processor 218 comprises K (an integer) quantum elements 122, which includes qubits (which could be of any type such as superconducting, spin qubits, ion trapped, etc.), and, where applicable, any other element(s) for processing quantum information, storing quantum information (e.g. storage resonator), and/or coupling the outbound quantum control pulses 213 and inbound quantum control pulses 215 between interconnect 212 and the quantum element(s) 122 (e.g., readout resonator(s)). In an example implementation in which the quantum processor comprises readout resonators (or other readout circuitry) K may be equal the total number of qubits plus the number of readout circuits. That is, if each of Q (an integer) qubits of the quantum processor 218 is associated with a dedicated readout circuit, then K may be equal to 2Q. For ease of description, the remainder of this disclosure will assume such an implementation, but it need not be the case in all implementations. Other elements of the quantum processor 218 may include, for example, flux lines (electronic lines for carrying current), gate electrodes (electrodes for voltage gating), current/voltage lines, amplifiers, classical logic circuits residing on-chip in the quantum processor 218, and/or the like.

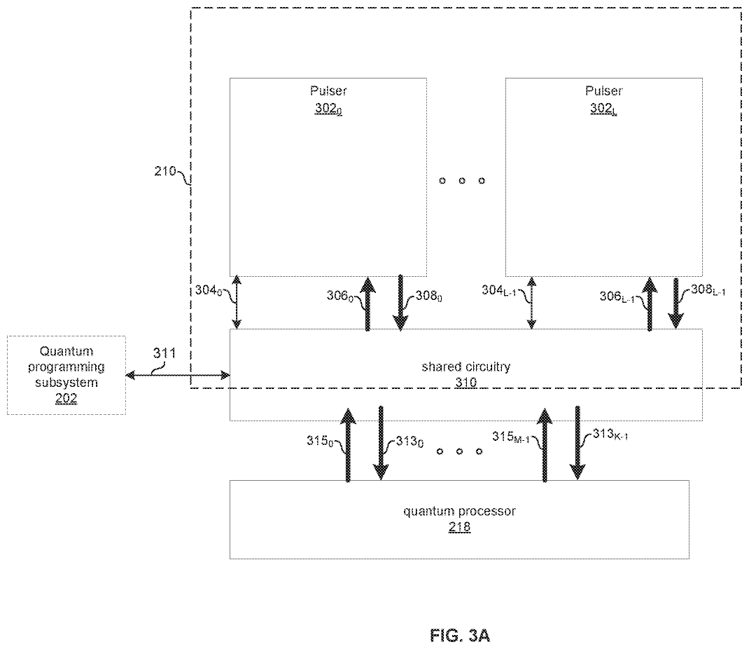

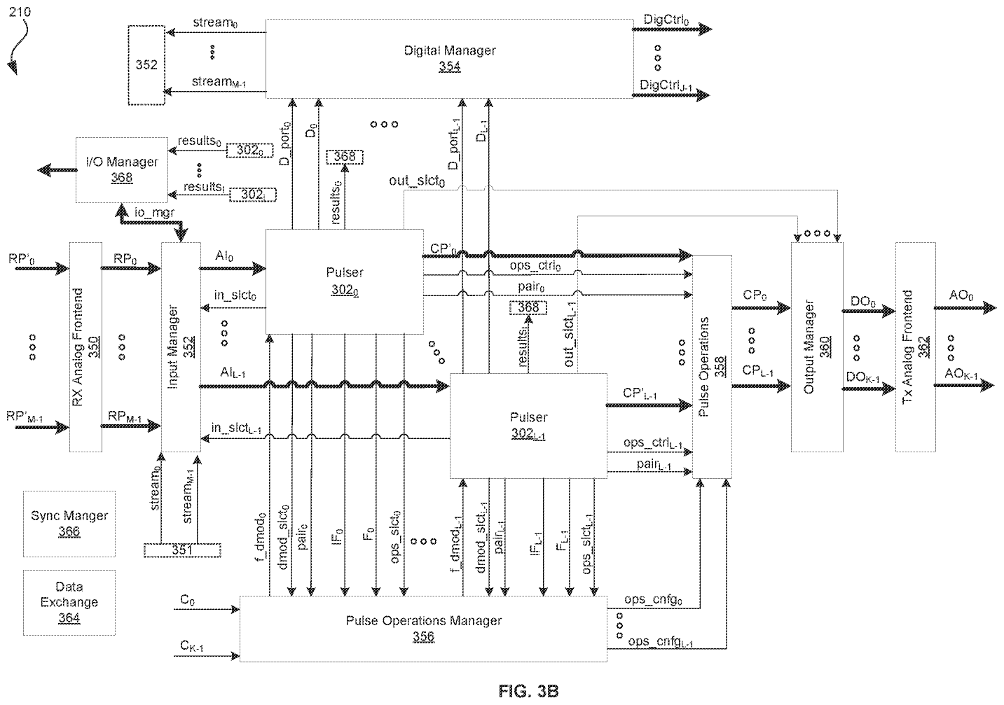

FIG. 3A shows an example quantum controller architecture in accordance with various example implementations of this disclosure. The quantum controller 210 comprises L (an integer ≥1) pulser circuits 302₀-302_{L-1} and shared circuitry 310.

In the example implementation shown, each pulser circuit 302_{I} (I an integer between 0 and L−1) comprises circuitry for exchanging information over signal paths 304_{I}, 306_{I}, and 308_{I}, where the signal path 308_{I} carries outbound pulses (e.g., 213 of FIG. 2) generated by the pulser circuit 302 (which may be, for example, control pulses sent to the quantum processor 128 to manipulate one or more properties of one or more quantum elements—e.g., manipulate a state of one or more qubits, manipulate a frequency of a qubit using flux biasing, etc., and/or readout a state of one or more quantum elements), the signal path 306_{I} carries inbound quantum element readout pulses (e.g., 215 of FIG. 2) to be processed by the pulser circuit 302_{I}, and signal path 304_{I} carries control information. Each signal path may comprise one or more conductors, optical channels, and/or wireless channels.

Each pulser circuit 302_{I} comprises circuitry operable to generate outbound pulses on signal path 308_{I} according to quantum control operations to be performed on the quantum processor 218. This involves very precisely controlling characteristics such as phase, frequency, amplitude, and timing of the outbound pulses. The characteristics of an outbound pulse generated at any particular time may be determined, at least in part, on inbound pulses received from the quantum processor 218 (via shared circuitry 310 and signal path 306) at a prior time. In an example implementation, the time required to close the feedback loop (i.e., time from receiving a first pulse on one or more of paths 315₁-315_{L} (e.g., at an analog to digital converter of the path) to sending a second pulse on one or more of paths 313₀-313_{L-1} (e.g., at an output of a digital-to-analog converter of the path), where the second pulse is based on the first pulse) is significantly less than the coherence time of the qubits of the quantum processor 218. For example, the time to close the feedback loop may be on the order of 100 nanoseconds. It should be noted that each signal path in FIG. 3A may in practice be a set of signal paths for supporting generation of multi-pulse sets (e.g., two signal paths for two-pulse pairs, three signal paths for three-pulse sets, and so on).

In the example implementation shown, the shared circuitry 310 comprises circuitry for exchanging information with the pulser circuits 302₀-302_{L-1} over signal paths 304₀-304_{L-1}, 306₀-306_{L-1}, and 308₀-308_{L-1}, where each signal path 308_{I} carries outbound pulses generated by the pulser circuit 302_{I}, each signal path 306_{I} carries inbound pulses to be processed by pulser circuit 302_{I}, and each signal path 304_{I} carries control information such as flag/status signals, data read from memory, data to be stored in memory, data streamed to/from the quantum programming subsystem 202, and data to be exchanged between two or more pulsers 302₀-302_{L}. Similarly, in the example shown the shared circuitry 310 comprises circuitry for exchanging information with the quantum processor 218 over signal paths 315₀-315_{M-1} and 313₁-313_{K-1}, where each signal path 315ₘ (m an integer between 0 and M−1) carries inbound pulses from the quantum processor 218, and each signal path 313ₖ (k an integer between 0 and K−1) carries outbound pulses to the quantum processor 218. Additionally, in the example shown the shared circuitry 310 comprises circuitry for exchanging information with the quantum programming subsystem over signal path 311. The shared circuitry 310 may be: integrated with the quantum controller (e.g., on the same field programmable gate array or application specific integrated circuitry or printed circuit board); external to the quantum controller (e.g., on a separate FPGA, ASIC, or PCB connected to the quantum controller via one or more cables, backplanes, in other devices connected to the quantum processor 218, etc.); or partially integrated with the quantum controller and partially external to the quantum controller.

In various implementations, M may be less than, equal to, or greater than L, K may be less than, equal to, or greater than L, and M may be less than, equal to, or greater than K. For example, the nature of some quantum algorithms is such that not all K quantum elements need to be driven at the same time. For such algorithms, L may be less than K and one or more of the L pulsers 302_{I} may be shared among multiple of the K quantum elements circuits. That is, any pulser 302_{I} may generate pulses for different quantum elements at different times. This ability of a pulser 302_{I} to generate pulses for different quantum elements at different times can reduce the number of pulsers 302₀-302_{L-1} (i.e., reduce L) required to support a given number of quantum elements (thus saving significant resources, cost, size, overhead when scaling to larger numbers of qubits, etc.).

The ability of a pulser 302_{I} to generate pulses for different quantum elements at different times also enables reduced latency. As just one example, assume a quantum algorithm which needs to send a pulse to quantum element 122₀ at time T1, but whether the pulse is to be of a first type or second type (e.g., either an X pulse or a Hadamard pulse) cannot be determined until after processing an inbound readout pulse at time T1-DT (i.e., DT time intervals before the pulse is to be output). If there were a fixed assignment of pulsers 302₀-302_{L-1} to quantum elements of the quantum processor 218 (i.e., if 302₀ could only send pulses to quantum element 122₀, and 302_{I} could only send pulses to quantum element 122₁, and so on), then pulser 302₀ might not be able to start generating the pulse until it determined what the type was to be. In the depicted example implementation, on the other hand, pulser 302₀ can start generating the first type pulse and pulser 302₁ can start generating the second type pulse and then either of the two pulses can be released as soon as the necessary type is determined. Thus, if the time to generate the pulse is Tₗₐₜ, in this example the example quantum controller 210 may reduce latency of outputting the pulse by Tₗₐₜ.

The shared circuitry 310 is thus operable to receive pulses via any one or more of the signals paths 308₀-308_{L-1} and/or 315₀-315_{M-1}, process the received pulses as necessary for carrying out a quantum algorithm, and then output the resulting processed pulses via any one or more of the signal paths 306₀-306_{L-1} and/or 313₀-313_{K-1}. The processing of the pulses may take place in the digital domain and/or the analog domain. The processing may comprise, for example: frequency translation/modulation, phase translation/modulation, frequency and/or time division multiplexing, time and/or frequency division demultiplexing, amplification, attenuation, filtering in the frequency domain and/or time domain, time-to-frequency-domain or frequency-to-time-domain conversion, upsampling, downsampling, and/or any other signal processing operation. At any given time, the decision as to from which signal path(s) to receive one or more pulse(s), and the decision as to onto which signal path(s) to output the pulse(s) may be: predetermined (at least in part) in the quantum algorithm description; and/or dynamically determined (at least in part) during runtime of the quantum algorithm based on classical programs/computations performed during runtime, which may involve processing of inbound pulses. As an example of predetermined pulse generation and routing, a quantum algorithm description may simply specify that a particular pulse with predetermined characteristics is to be sent to signal path 313₁ at a predetermined time. As an example of dynamic pulse determination and routing, a quantum algorithm description may specify that an inbound readout pulse at time T-DT should be analyzed and its characteristics (e.g., phase, frequency, and/or amplitude) used to determine, for example, whether at time T pulser 302_{I} should output a pulse to a first quantum element or to a second quantum element or to determine, for example, whether at time T pulser 302_{I} should output a first pulse to a first quantum element or a second pulse to the first quantum element. In various implementations of the quantum controller 210, the shared circuitry 310 may perform various other functions instead of and/or in addition to those described above. In general, the shared circuitry 310 may perform functions that are desired to be performed outside of the individual pulser circuits 302₀-302_{L-1}. For example, a function may be desirable to implement in the shared circuitry 310 where the same function is needed by a number of pulser circuits from 302₀-302_{L-1} and thus may be shared among these pulser circuits instead of redundantly being implemented inside each pulser circuit. As another example, a function may be desirable to implement in the shared circuitry 310 where the function is not needed by all pulser circuits 302₀-302_{L-1} at the same time and/or on the same frequency and thus fewer than L circuits for implementing the function may be shared among the L pulser circuits 302₀-302_{L-1} through time and/or frequency division multiplexing. As another example, a function may be desirable to implement in the shared circuitry 310 where the function involves making decisions based on inputs, outputs, and/or state of multiple of the L pulser circuits 302₀-302_{L-1}, or other circuits. Utilizing a centralized coordinator/decision maker in the shared circuitry 310 may have the benefit(s) of: (1) reducing pinout and complexity of the pulser circuits 302₀-302_{L-1}; and/or (2) reducing decision-making latency. Nevertheless, in some implementations, decisions affecting multiple pulser circuits 302₀-302_{L-1} may be made by one or more of the pulser circuits 302₀-302_{L-1} where the information necessary for making the decision can be communicated among pulser circuits within a suitable time frame (e.g., still allowing the feedback loop to be closed within the qubit coherence time) over a tolerable number of pins/traces.

FIG. 3B shows an example implementation of the quantum controller of FIG. 2. The example quantum controller shown comprises pulsers 302₁-302_{L-1}, receive analog frontend 350, input manager 352, digital manager 354, pulse operations manager 356, pulse operations 358, output manager 360, transmit analog frontend 362, data exchange 364, synchronization manager 366, and input/output (“I/O”) manager 368. Circuitry depicted in FIG. 3B other than pulser circuits 302₀-302_{L-1} corresponds to an example implementation of the shared circuitry 310 of FIG. 3A.

The receive analog frontend 350 comprises circuitry operable to concurrently process up to M (an integer ≥1) analog inbound signals (RP′₀-RP′_{M-1}) received via signal paths 315₀-315_{M-1} to generate up to M concurrent inbound signals (RP₀-RP_{M-1}) to be output to input manager 352 via one or more signal paths. Although there is shown to be M signals RP and M signals RP′, this need not be the case. Such processing may comprise, for example, analog-to-digital conversion, filtering, upconversion, downconversion, amplification, attenuation, time division multiplexing/demultiplexing, frequency division multiplexing/demultiplexing, and/or the like. In various implementations, M may be less than, equal to, or greater than L and M may be less than, equal to, or greater than K.

The input manager 352 comprises circuitry operable to route any one or more of signals (RP₀-RP_{M-1}) to any one or more of pulsers 302₀-302_{L-1} (as signal(s) Al₀-Al_{L-1}) and/or to other circuits (e.g. as signal io_mgr to I/O manager 368). In an example implementation, the input manager 352 comprises one or more switch networks, multiplexers, and/or the like for dynamically reconfiguring which signals RP₀-RP_{M-1} are routed to which pulsers 302₀-302_{L-1}. This may enable time division multiplexing multiple of the signals RP₀-RP_{M-1} onto a single signal Al_{I} and/or time division demultiplexing components (e.g., time slices) of a signal RPₘ onto multiple of the signals Al₀-Al_{L-1}. In an example implementation, the input manager 352 comprises one or more mixers and/or filters for frequency division multiplexing multiple of the signals RP₀-RP_{M-1} onto a single signal Al_{I} and/or frequency division demultiplexing components (e.g., frequency bands) of a signal RPₘ onto multiple of the signals Al₀-Al_{L-1}. The signal routing and multiplexing/demultiplexing functions performed by the input manager 352 enables: a particular pulser 302_{I} to process different inbound pulses from different quantum elements at different times; a particular pulser 302_{I} to process different inbound pulses from different quantum elements at the same time; and multiple of the pulsers 302₀-302_{L-1} to processes the same inbound pulse at the same time. In the example implementation shown, routing of the signals RP₀-RP_{M-1} among the inputs of the pulsers 302₀-302_{L-1} is controlled by digital control signals in_slct₀-in_slct_{L-1} from the pulsers 302₀-302_{L-1}. In another implementation, the input manager may be operable to autonomously determine the appropriate routing (e.g., where the quantum algorithm description includes instructions to be loaded into memory of, and executed by, the input manager 352). In the example implementation, the input manager 352 is operable to rout input signals RP₀-RP_{M-1} to the I/O manager 368 (as signal(s) io_mgr), to be sent to the quantum programing subsystem 202. This routing may, for example, be controlled by signals from the digital manager 354. In an example implementation, for each input signal RPₘ there is a digital signal, streamₘ, from the digital manager 354 to the input manager 352 that controls whether RPₘ will be sent from the input manager 352 to the I/O manager 368 and from there to the quantum programing subsystem 202.

Each of the pulsers 302₀-302_{L-1} is as described above with reference to FIG. 3A. In the example implementation shown, each pulser 302, is operable to generate raw outbound pulses CP′_{I} (“raw” is used simply to denote that the pulse has not yet been processed by pulse operations circuitry 358) and digital control signals in_slct_{I}, D_port_{I}, D_{I}, out_slct_{I}, ops_ctrl_{I}, ops_slct_{I}, IF_{I}, F_{I}, and dmod_sclt_{I} for carrying out quantum algorithms on the quantum processor 218, and results for carrying intermediate and/or final results generated by the pulser 302_{I} to the quantum programming subsystem 202. One or more of the pulsers 302₀-302_{L-1} may receive and/or generate additional signals which are not shown in FIG. 3A for clarity of illustration. The raw outbound pulses CP′₀-CP′_{L-1} are conveyed via signal paths 308₀-308_{L-1} and the digital control signals are conveyed via signal paths 304₀-304_{L-1}. Each of the pulsers 302_{I} is operable to receive inbound pulse signal Al_{I} and signal f_dmod_{I}. Pulser 302_{I} may process the inbound signal Al_{I} to determine the state of certain quantum element(s) in the quantum processor 218 and use this state information for making decisions such as, for example, which raw outbound pulse CP′_{I} to generate next, when to generate it, and what control signals to generate to affect the characteristics of that raw outbound pulse appropriately. Pulser 302_{I} may use the signal f_dmod_{I} for determining how to process inbound pulse signal Al_{I}. As an example, when pulser 302₁ needs to process an inbound signal Al₁ from quantum element 122₃, it can send a dmod_sclt₁ signal that directs pulse operations manager 356 to send, on f_dmod₁, settings to be used for demodulation of an inbound signal Al₁ from quantum element 122₃ (e.g., the pulse operations manager 356 may send the value cos(@3*TS*T_{clk1}+ϕ₃), where ω₃ is the frequency of quantum element 122₃, TS is amount of time passed since the reference point, for instance the time at which quantum algorithm started running, and ϕ₃ is the phase of the total frame rotation of quantum element 122₃, i.e. the accumulated phase of all frame rotations since the reference point).

The pulse operations circuitry 358 is operable to process the raw outbound pulses CP′₀-CP′_{L-1} to generate corresponding output outbound pulses CP₀-CP_{L-1}. This may comprise, for example, manipulating the amplitude, phase, and/or frequency of the raw pulse CP′_{I}. The pulse operations circuitry 358 receives raw outbound pulses CP′₀-CP′_{L-1} from pulsers 302₀-302_{L-1}, control signals ops_cnfg₀-ops_cnfg_{L-1} from pulse operations manager 356, and ops_ctrl₀-ops_ctrl_{L-1} from pulsers 302₀-302_{L-1}.

The control signal ops_cnfg_{I} configures, at least in part, the pulse operations circuitry 358 such that each raw outbound pulse CP′_{I} that passes through the pulse operations circuitry 358 has performed on it one or more operation(s) tailored for that particular pulse. To illustrate, denoting a raw outbound pulse from pulser 3023 at time T1 as CP′_{3,T1}, then, at time T1 (or sometime before T1 to allow for latency, circuit setup, etc.), the digital control signal ops_cnfg₃ (denoted ops_cnfg_{3,T1} for purposes of this example) provides the information (e.g., in the form of one or more matrix, as described below) as to what specific operations are to be performed on pulse CP′_{3,T1}. Similarly, ops_cnfg_{4,T1} provides the information as to what specific operations are to be performed on pulse CP′_{4,T1}, and ops_cnfg_{3,T2} provides the information as to what specific operations are to be performed on pulse CP′_{4,T1}.

The control signal ops_ctrl_{I} provides another way for the pulser 302_{I} to configure how any particular pulse is processed in the pulse operations circuitry 358. This may enable the pulser 302_{I} to, for example, provide information to the pulse operation circuitry 358 that does not need to pass through the pulse operation manager 356. For example, the pulser 302_{I} may send matrix values calculated in real-time by the pulser 302_{I} to be used by the pulse operation circuitry 358 to modify pulse CP′_{I}. These matrix values arrive to the pulse operation circuitry 358 directly from the pulser 302_{I} and do not need to be sent to the pulse operation manager first. Another example may be that the pulser 302_{I} provides information to the pulse operation circuitry 358 to affect the operations themselves (e.g. the signal ops_ctrl_{I} can choose among several different mathematical operations that can be performed on the pulse).

The pulse operations manager 356 comprises circuitry operable to configure the pulse operations circuitry 358 such that the pulse operations applied to each raw outbound pulse CP′_{I} are tailored to that particular raw outbound pulse. To illustrate, denoting a first raw outbound pulse to be output during a first time interval T1 as CP′_{I,T1}, and a second raw outbound pulse to be output during a second time interval T2 as CP′_{I,T2}, then pulse operations circuitry 358 is operable to perform a first one or more operations on CP′_{I,T1} and a second one or more operations on CP′_{1,T2}. The first one or more operations may be determined, at least in part, based on to which quantum element the pulse CP_{1,T1} is to be sent, and the second one or more operations may be determined, at least in part, based on to which quantum element the pulse CP_{1,T2} is to be sent. The determination of the first one or more operations and second one or more operations may be performed dynamically during runtime.

The transmit analog frontend 362 comprises circuitry operable to concurrently process up to K digital signals DOₖ to generate up to K concurrent analog signals AOₖ to be output to the quantum processor 218. Such processing may comprise, for example, digital-to-analog conversion, filtering, upconversion, downconversion, amplification, attenuation, time division multiplexing/demultiplexing, frequency division multiplexing/demultiplexing and/or the like. In an example implementation, each of the one or more of signal paths 313₀-313_{K-1} (FIG. 3A) represents a respective portion of Tx analog frontend circuit 362 as well as a respective portion of interconnect 212 (FIG. 2) between the Tx analog frontend circuit 362 and the quantum processor 218. Although there is one-to-one correspondence between the number of DO signals and the number of AO signals in the example implementation described here, such does not need to be the case. In another example implementation, the analog frontend 362 is operable to map more (or fewer) signals DO to fewer (or more) signals AO. In an example implementation the transmit analog frontend 362 is operable to process digital signals DO₀-DO_{K-1} as K independent outbound pulses, as K/2 two-pulse pairs, or process some of signals DO₀-DO_{K-1} as independent outbound pulses and some signals DO₀-DO_{K-1} as two-pulse pairs (at different times and/or concurrently.

The output manager 360 comprises circuitry operable to route any one or more of signals CP₀-CP_{L-1} to any one or more of signal paths 313₀-313_{K-1}. As just one possible example, signal path 313₀ may comprise a first path through the analog frontend 362 (e.g., a first mixer and DAC) that outputs AO₀ and traces/wires of interconnect 212 that carry signal AO₀; signal path 313₁ may comprise a second path through the analog frontend 362 (e.g., a second mixer and DAC) that outputs AO₁ and traces/wires of interconnect 212 that carry signal AO₁, and so on. In an example implementation, the output manager 360 comprises one or more switch networks, multiplexers, and/or the like for dynamically reconfiguring which one or more signals CP₀-CP_{L-1} are routed to which signal paths 313₀-313_{K-1}. This may enable time division multiplexing multiple of the signals CP₀-CP_{L-1} onto a single signal path 313ₖ and/or time division demultiplexing components (e.g., time slices) of a signal CPₘ onto multiple of the signal paths 313₀-313_{K-1}. In an example implementation, the output manager 360 comprises one or more mixers and/or filters for frequency division multiplexing multiple of the signals CP₀-CP_{M-1} onto a single signal path 313ₖ and/or frequency division demultiplexing components (e.g., frequency bands) of a signal CPₘ onto multiple of the signal paths 313₀-313_{K-1}. The signal routing and multiplexing/demultiplexing functions performed by the output manager 360 enables: routing outbound pulses from a particular pulser 302_{I} to different ones of the signal paths 313₀-313_{K-1} at different times; routing outbound pulses from a particular pulser 302_{I} to multiple of the signal paths 313₀-313_{K-1} at the same time; and multiple of the pulsers 302₀-302_{L-1} generating pulses for the same signal path 313ₖ at the same time. In the example implementation shown, routing of the signals CP₀-CP_{L-1} among the signal paths 313₀-313_{K-1} is controlled by digital control signals out_slct₀-out_slct_{L-1} from the pulsers 302₀-302_{L-1}. In another implementation, the output manager 360 may be operable to autonomously determine the appropriate routing (e.g., where the quantum algorithm description includes instructions to be loaded into memory of, and executed by, the output manager 360). In an example implementation, at any given time, the output manager 360 is operable to concurrently route K of the digital signals CP₀-CP_{L-1} as K independent outbound pulses, concurrently route K/2 of the digital signals CP₀-CP_{L-1} as two-pulse pairs, or route some of signals CP₀-CP_{L-1} as independent outbound pulses and some others of the signals CP₀-CP_{L-1} as multi-pulse sets (at different times and/or concurrently).

The digital manager 354 comprises circuitry operable to process and/or route digital control signals (DigCtrl₀-DigCtrl_{J-1}) to various circuits of the quantum controller 210 and/or external circuits coupled to the quantum controller 210. In the example implementation shown, the digital manager receives, from each pulser 302_{I}, (e.g., via one or more of signal paths 304₀-304_{N-1}) a digital signal D_{I} that is to be processed and routed by the digital manager 354, and a control signal D_port_{I} that indicates to which output port(s) of the digital manager 354 the signal D_{I} should be routed. The digital control signals may be routed to, for example, any one or more of circuits shown in FIG. 3B, switches/gates which connect and disconnect the outputs AO₀-AO_{K-1} from the quantum processor 218, external circuits coupled to the quantum controller 210 such as microwave mixers and amplifiers, and/or any other circuitry which can benefit from on real-time information from the pulser circuits 302₀-302_{L-1}. Each such destination of the digital signals may require different operations to be performed on the digital signal (such as delay, broadening, or digital convolution with a given digital pattern). These operations may be performed by the digital manager 354 and may be specified by control signals from the pulsers 302₀-302_{L-1}. This allows each pulser 302_{I} to generate digital signals to different destinations and allows different ones of pulsers 302₀-302_{L-1} to generate digital signals to the same destination while saving resources.

The synchronization manager 366 comprises circuitry operable to manage synchronization of the various circuits shown in FIG. 3B. Such synchronization is advantageous in a modular and dynamic system, such as quantum controller 210, where different ones of pulsers 302₀-302_{L-1} generate, receive, and process pulses to and from different quantum elements at different times. For example, while carrying out a quantum algorithm, a first pulser circuit 302_{I} and a second pulser circuit 302₂ may sometimes need to transmit pulses at precisely the same time and at other times transmit pulses independently of one another. In the example implementation shown, the synchronization manager 366 reduces the overhead involved in performing such synchronization.

The data exchange circuitry 364 is operable to manage exchange of data among the various circuits shown in FIG. 3B. For example, while carrying out a quantum algorithm, first pulser circuit 302₁ and a second pulser circuit 302₂ may sometimes need to exchange information. As just one example, pulser 302₁ may need to share, with pulser 302₂, the characteristics of an inbound signal Al₁ that it just processed so that pulser 302₂ can generate a raw outbound pulse CP′₂ based on the characteristics of Al₁. The data exchange circuitry 364 may enable such information exchange. In an example implementation, the data exchange circuitry 364 may comprise one or more registers to and from which the pulsers 302₀-302_{L-1} can read and write.

The I/O manager 368 is operable to route information between the quantum controller 210 and the quantum programming subsystem 202.

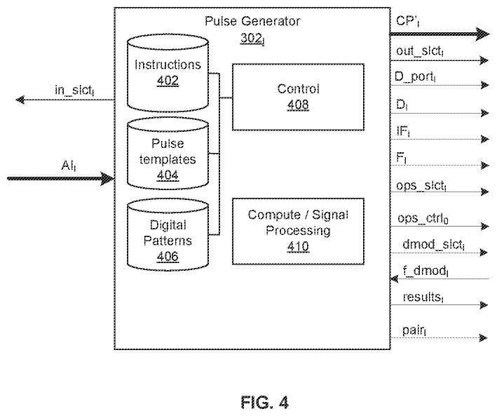

FIG. 4 shows an example implementation of the pulser of FIG. 3B. The example pulser 302_{I} shown comprises instruction memory 402, pulse template memory 404, digital pattern memory 406, control circuitry 408, and compute and/or signal processing circuitry (CSP) 410.

The memories 402, 404, 406 may comprise one or more be any type of suitable storage elements (e.g., DRAM, SRAM, Flash, etc.). The instructions stored in memory 402 are instructions to be executed out by the pulser 302_{I} for carrying out its role in a quantum algorithm. Because different pulsers 302₀-302_{L-1} have different roles to play in any particular quantum algorithm (e.g., generating different pulses at different times), the instructions memory 402 for each pulser 302_{I} may be specific to that pulser. For example, the quantum algorithm description 206 from the quantum programming subsystem 202 may comprise a first set of instructions to be loaded (via I/O manager 368) into pulser 302₀, a second set of instructions to be loaded into pulser 302₁, and so on. Each pulse template stored in memory 404 comprises a sequence of one or more samples of any arbitrary shape (e.g., Gaussian, sinc, impulse, etc.) representing the pulses to be sent to pulse operation circuitry 358. Each digital pattern stored in memory 406 comprises a sequence of one or more binary values which may represent the digital pulses to be sent to the digital manager 354 for generating digital control signals DigCtrl₀-DigCtrl_{J-1}.

The control circuitry 408 is operable to execute the instructions stored in memory 402 to process inbound signal Al_{I}, generate raw outbound pulses CP′_{I}, and generate digital control signals in_slct_{I}, out_slct_{I}, D_port_{I}, D_{I}, IF_{I}, F_{I}, ops_slct_{I}, ops_ctrl_{I}, results_{I}, dmod_slct_{I} and pair_{I}. In the example implementation shown, the processing of the inbound signal Al_{I} is performed by the CSP circuitry 410 and based (at least in part) on the signal f_dmod_{I}.

The compute and/or signal processing circuitry (CSP) 410 is operable to perform computational and/or signal processing functions, which may comprise, for example Boolean-algebra based logic and arithmetic functions and demodulation (e.g., of inbound signals Al_{I}).

In operation of an example implementation, generation of a raw outbound pulse CP′_{I} comprises the control circuitry 408: (1) determining a pulse template to retrieve from memory 404 (e.g., based on a result of computations and/or signal processing performed by the CSP 410); (2) retrieving the pulse template; (3) performing some preliminary processing on the pulse template; (4) determining the values of F, IF, pair_{I}, ops_slct_{I}, and dmod_slct_{I} to be sent to the pulse operation manager 356 (as predetermined in the quantum algorithm description and/or determined dynamically based on results of computations and/or signal processing performed by the CSP 410); (5) determining the value of ops_ctrl_{I} to be sent to the pulse operation circuitry 358; (6) determining the value of in_slct_{I} to be sent to the input manager 352; (7) determining a digital pattern to retrieve from memory 406 (as predetermined in the quantum algorithm description and/or determined dynamically based on results of computations and/or signal processing performed by the CSP 410); (8) outputting the digital pattern as D_{I} to the digital manager along with control signal D_port_{I} (as predetermined in the quantum algorithm description and/or determined dynamically based on results of computations and/or signal processing performed by the CSP 410); (9) outputting the raw outbound pulse CP′_{I} to the pulse operations circuitry 358; (10) outputting results, to the I/O manager.

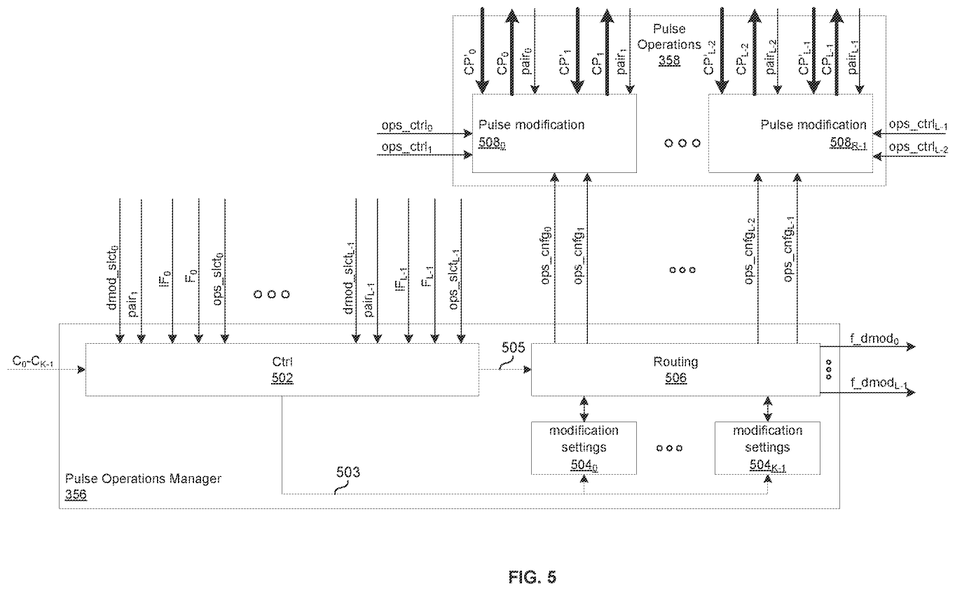

FIG. 5 shows an example implementation of the pulse operations manager and pulse operations circuitry of FIG. 3B. The pulse operations circuitry 358 comprises a plurality of pulse modification circuits 508₀-508_{R-1} (R is an integer ≥1 in general, and R=L/2 in the example shown). The pulse operations manager 356 comprises control circuitry 502, routing circuitry 506, and a plurality of modification settings circuits 504₀-504_{K-1}.

Although the example implementation has a 1-to-2 correspondence between pulse modification circuits 508₀-508_{R-1} and pulser circuits 302₀-302_{L-1}, that does not need to be the case. In other implementations there may be fewer pulse modification circuits 508 than pulser circuits 302. Similarly, other implementations may comprise more pulse modification circuits 508 than pulser circuits 302.

As an example, in some instances, two of the pulsers 302₀-302_{L-1} may generate two raw outbound pulses which are a phase-quadrature pulse pair. For example, assuming CP₁ and CP₂ are a phase-quadrature pulse pair to be output on path 3133. In this example, pulse operations circuitry 358 may process CP₁ and CP₂ by multiplying a vector representation of CP′₁ and CP′₂ by one or more 2 by 2 matrices to: (1) perform single-sideband-modulation, as given by

$$( \begin{matrix}C {P}_{1} \\ C {P}_{2}\end{matrix} ) = ( \begin{matrix}cos ( ω * TS * {T}_{c l c k 1} ) & - s in ( ω * TS * {T}_{c l c k 1} ) \\ sin ( ω * TS * {T}_{c l c k 1} ) & cos ( ω * TS * {T}_{c l c k 1} )\end{matrix} ) ( \begin{matrix}{CP}_{1}^{′} \\ {CP}_{2}^{′}\end{matrix} ) ,$$

where ω is the frequency of the single side band modulation and TS is the time passed since the reference time (e.g. the beginning of a certain control protocol); (2) keep track of frame-of-reference rotations, as given by

$$( \begin{matrix}C {P}_{1} \\ C {P}_{2}\end{matrix} ) = ( \begin{matrix}cos ( ϕ ) & - s in ( ϕ ) \\ sin ( ϕ ) & cos ( ϕ )\end{matrix} ) ( \begin{matrix}{CP}_{1}^{′} \\ {CP}_{2}^{′}\end{matrix} ) ,$$

where ϕ is the total phase that the frame of reference accumulated since the reference time; and/or (3) perform an IQ-mixer correction

$$( \begin{matrix}C {P}_{1} \\ C {P}_{2}\end{matrix} ) = ( \begin{matrix}{C}_{00} & {C}_{01} \\ {C}_{10} & {C}_{11}\end{matrix} ) ( \begin{matrix}{CP}_{1}^{′} \\ {CP}_{2}^{′}\end{matrix} ) ,$$

where C₀₀, C₀₁, C₁₀, and C₁₁ are the elements of a matrix that corrects for IQ-mixer imperfections. In an example implementation, each modification settings circuit, 504ₖ, contains registers that contain the matrix elements of three matrices:

$${C}_{k} = ( \begin{matrix}{C}_{k 00} & {C}_{k 01} \\ {C}_{k 10} & {C}_{k 11}\end{matrix} ) ,$$

an IQ-mixer correction matrix;

$${S}_{k} = ( \begin{matrix}cos ( {ω}_{k} * TS * {T}_{clck 1} ) & - sin ( {ω}_{k} * TS ) * {T}_{clck 1} \\ sin ( {ω}_{k} * TS * {T}_{clck 1} ) & cos ( {ω}_{k} * TS * {T}_{clck 1} )\end{matrix} ) ,$$

a single side band frequency modulation matrix; and

$${F}_{k} = ( \begin{matrix}cos ( {ϕ}_{k} ) & - s in ( {ϕ}_{k} ) \\ sin ( {ϕ}_{k} ) & cos ( {ϕ}_{k} )\end{matrix} ) ,$$

a frame rotation matrix, which rotates the IQ axes around the axis perpendicular to the IQ plane (i.e. the z-axis if I and Q are the x-axis and y-axis). In an example implementation, each modification settings circuit 504ₖ also contains registers that contain the elements of the matrix products CₖSₖFₖ and SₖFₖ.

In the example shown, each pulse modification circuit 508ᵣ is operable to process two raw outbound pulses CP′₂ᵣ and CP′₂ᵣ₊₁ according to: the modification settings ops_cnfg₂ᵣ and ops_cnfg₂ᵣ₊₁; the signals ops_ctrl₂ᵣ and ops_ctrl₂ᵣ₊₁; and the signals pair₂ᵣ and pair₂ᵣ₊₁. In an example implementation pair₂ᵣ and pair₂ᵣ₊₁ may be communicated as ops_ctrl₂ᵣ and ops_ctrl₂ᵣ₊₁. The result of the processing is outbound pulses CP₂ᵣ and CP₂ᵣ₊₁. Such processing may comprise adjusting a phase, frequency, and/or amplitude of the raw outbound pulses CP′₂ᵣ and CP′₂ᵣ₊₁. In an example implementation, ops_cnfg₂ᵣ and ops_cnfg₂ᵣ₊₁ are in the form of a matrix comprising real and/or complex numbers and the processing comprises matrix multiplication involving a matrix representation of the raw outbound pulses CP₂ᵣ and CP₂ᵣ₊₁ and the ops_cnfg₂ᵣ and ops_cnfg₂ᵣ₊₁ matrix.

The control circuitry 502 is operable to exchange information with the pulser circuits 302₀-302_{L-1} to generate values of ops_confg₀-ops_confg_{L-1} and f_demod₀-f_demod_{L-1}, to control routing circuitry 506 based on signals ops_slct₀-ops_slct_{L-1} and dmod_slct₀-dmod_slct_{L-1}, and to update pulse modification settings 504₀-504_{K-1} based on IF₀-IF_{L-1} and F₀-F_{L-1} such that pulse modification settings output to pulse operations circuitry 358 are specifically tailored to each raw outbound pulse (e.g., to which quantum element 222 the pulse is destined, to which signal path 313 the pulse is destined, etc.) to be processed by pulse operations circuitry 358.

Each modification settings circuit 504ₖ comprises circuitry operable to store modification settings for later retrieval and communication to the pulse operations circuitry 358. The modification settings stored in each modification settings circuit 504ₖ may be in the form of one or more two-dimensional complex-valued matrices. Each signal path 313₀-313_{K-1} may have particular characteristics (e.g., non-idealities of interconnect, mixers, switches, attenuators, amplifiers, and/or circuits along the paths) to be accounted for by the pulse modification operations. Similarly, each quantum element 122₀-122ₖ may have a particular characteristics (e.g. resonance frequency, frame of reference, etc.). In an example implementation, the number of pulse modification settings, K, stored in the circuits 504 corresponds to the number of quantum element 122₀-122_{K-1} and of signal paths 313₀-313_{K-1} such that each of the modification settings circuits 504₀-504_{K-1} stores modification settings for a respective one of the quantum elements 122₀-122_{K-1} and/or paths 313₀-313_{K-1}. In other implementations, there may be more or fewer pulse modification circuits 504 than signal paths 313 and more or fewer pulse modification circuits 504 than quantum elements 122 and more or fewer signal paths 313 than quantum elements 122. The control circuitry 502 may load values into the modification settings circuit 504₀-504_{K-1} via signal 503.

The routing circuitry 506 is operable to route modification settings from the modification settings circuits 504₀-504_{L-1} to the pulse operations circuit 358 (as ops_confg₀-ops_confg_{L-1}) and to the pulsers 302₀-302_{L-1} (as f_dmod₀-f_dmod_{L-1}). In the example implementation shown, which of the modification settings circuits 504₀-504_{K-1} has its/their contents sent to which of the pulse modification circuits 508₀-508_{R-1} and to which of the pulsers 302₀-302_{L-1} is controlled by the signal 505 from the control circuitry 502.

The signal ops_slct_{I} informs the pulse operations manager 356 as to which modification settings 504ₖ to send to the pulse modification circuit 508_{I}. The pulser 302_{I} may determine ops_slct_{I} based on the particular quantum element 122ₖ and/or signal path 313ₖ to which the pulse is to be transmitted (e.g., the resonant frequency of the quantum element, frame of reference, and/or mixer correction). The determination of which quantum element and/or signal path to which a particular pulser 302_{I} is to send an outbound pulse at a particular time may be predetermined in the quantum algorithm description or may be determined based on calculations performed by the pulser 302_{I} and/or others of the pulsers 302₀-302_{L-1} during runtime. The control circuitry 502 may then use this information to configure the routing block 506 such that the correct modification settings are routed to the correct one or more of the pulse modification circuits 508₀-508_{L-1}.

In an example implementation, the digital signal IF_{I} instructs the pulse operations manager 356 to update a frequency setting of the modification settings circuit 504ₖ indicated by ops_slct_{I}. In an example implementation, the frequency setting is the matrix Sₖ (described above) and the signal IF_{I} carries new values indicating the new ωₖ to be used in the elements of the matrix Sₖ. The new values may, for example, be determined during a calibration routine (e.g., performed as an initial portion of the quantum algorithm) in which one or more of the pulsers 302₀-302_{L-1} sends a series of outbound pulses CP, each at a different carrier frequency, and then measures the corresponding inbound signals Al.

In an example implementation, the signal F_{I} instructs the pulse operations manager 356 to update a frame setting of the modification settings circuit 504ₖ indicated by ops_slct_{I}. In an example implementation, the frame setting is the matrix Fₖ (described above) and the signal F_{I} carries a rotation matrix F_{I} which multiplies with Fₖ to rotate Fₖ. This can be written as

$${F}_{k} = {F}_{1} {F}_{k} = ( \begin{matrix}cos ( Δϕ ) & - sin ( Δϕ ) \\ sin ( Δϕ ) & cos ( Δϕ )\end{matrix} ) ( \begin{matrix}cos ( {ϕ}_{k} ) & - sin ( {ϕ}_{k} ) \\ sin ( {ϕ}_{k} ) & cos ( {ϕ}_{k} )\end{matrix} ) = ( \begin{matrix}cos ( {ϕ}_{k} + Δ ϕ ) & - sin ( {ϕ}_{k} + Δ ϕ ) \\ sin ( {ϕ}_{k} + Δ ϕ ) & cos ( {ϕ}_{k} + Δ ϕ )\end{matrix} ) ,$$

where ϕₖ is the frame of reference before the rotation and Δϕ is the amount by which to rotate the frame of reference. The pulser 302_{I} may determine Δϕ based on a predetermined algorithm or based on calculations performed by the pulsers 302_{I} and/or others of the pulsers 302₀-302_{L-1} during runtime.

In an example implementation, the signal dmod_sclt_{I} informs the pulse operations manager 356 from which of the modification settings circuits 504ₖ to retrieve values to be sent to pulser 302_{I} as f_dmod_{I}. The pulser 302_{I} may determine dmod_slct_{I} based on the particular quantum element 122ₖ and/or signal path 315ₖ from which the pulse to be processed arrived. The determination of from which quantum element and/or signal path a particular pulser 302_{I} is to process an inbound pulse at a particular time may be predetermined in the quantum algorithm description or may be determined based on calculations performed by the pulser 302_{I} and/or others of the pulsers 302₀-302_{L-1} during runtime. The control circuitry 502 may then use this information to configure the routing block 506 such that the correct modification settings are routed to the correct one of the pulsers 302₀-302_{L-1}. For example, when pulse generation circuit 302_{I} needs to demodulate a pulse signal Al_{I} from quantum element 122ₖ, it will send a dmod_sclt_{I} signal instructing the pulse operation manager 356 to rout the element SFₖ₀₀=cos(ωₖ*time_stamp+ϕₖ) from modification settings circuit 504ₖ to pulser 302_{I} (as f_dmod_{I}).

In the example implementation shown, the digital signals C₀-C_{K-1} provide information about signal-path-specific modification settings to be used for each of the signal paths 313₀-313_{K-1}. For example, each signal Cₖ may comprise a matrix to be multiplied by a matrix representation of a raw outbound pulse CP′_{I} such that the resulting output outbound pulse is pre-compensated for errors (e.g., resulting from imperfections in mixers, amplifiers, wiring, etc.) introduced as the outbound pulse propagates along signal path 313ₖ. The result of the pre-compensation is that output outbound pulse CP_{I} will have the proper characteristics upon arriving at the quantum processor 218. The signals C₀-C_{K-1} may, for example, be calculated by the quantum controller 210 itself, by the programming subsystem 202, and/or by external calibration equipment and provided via I/O manager 368. The calculation of signals may be done as part of a calibration routine which may be performed before a quantum algorithm and/or may be determined/adapted in real-time as part of a quantum algorithm (e.g., to compensate for temperature changes during the quantum algorithm).

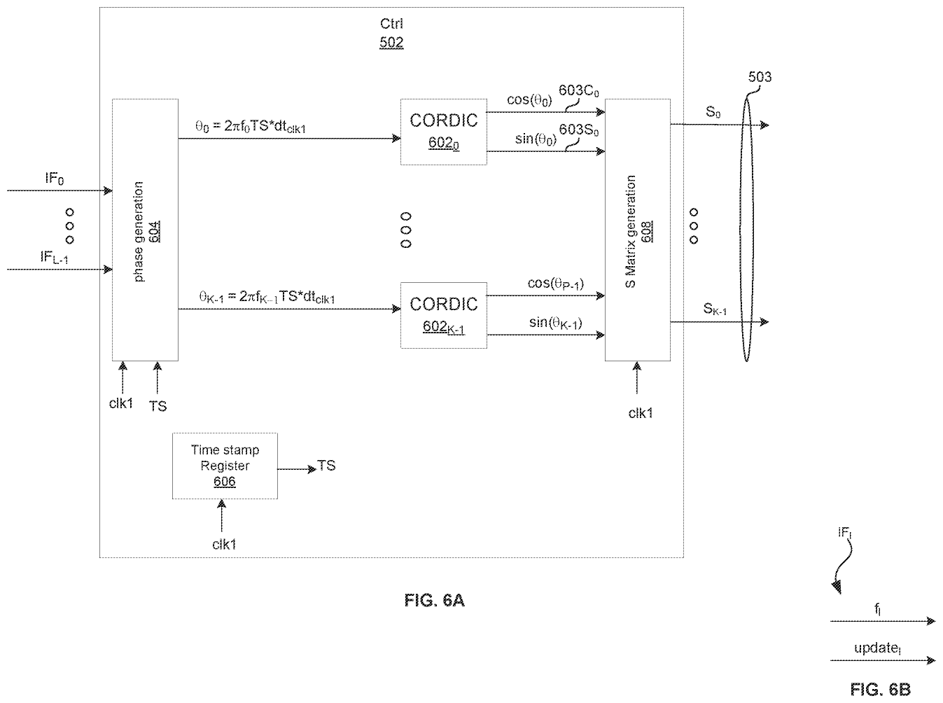

FIG. 6A shows frequency generation circuitry of the quantum controller of FIG. 3B. In the example implementation shown, the frequency generation circuitry is part of control circuitry 502 of pulse operations manager circuitry 356. The frequency generation circuitry comprises K coordinate rotation digital computer (CORDIC) circuits 602₀-602_{K-1}, phase generation circuitry 604, timestamp register 606, and S-Matrix generation circuitry 608.

Each CORDIC circuit 602ₖ is operable to compute cosine and sine of its input, θₖ, thus generating two signals cos(θₖ) and sin(θₖ).

The phase generation circuitry 604 is operable to generate the CORDIC input parameters θ₀-θ_{K-1} based on: (1) the frequency setting signals IF₀-IF_{L-1} from the pulsers 302₀-302_{L-1}; and (2) the contents, TS, of the timestamp register 606.

The timestamp register 606 comprises circuitry (e.g., a counter incremented on each cycle of the clock signal clk1) operable to track the number of cycles of clk1 since a reference point in time (e.g., power up of the quantum controller 210, start of execution of set of instructions of a quantum algorithm by the quantum controller 210, etc.).

In the example shown, the phase generation circuitry 604 sets θ₀=2πf₀(TS)(dt_{clk1}), where f₀ is a frequency determined from the signal IF₀, TS is the number of clock cycles counted from the reference point and dt_{clk1} is the duration of a single clock cycle of clk1. This leads to the CORDIC outputs being a pair of phase-quadrature reference signals, cos(2πf₀(TS)(dt_{clk1})) and sin(2πf₀(TS)(dt_{clk1})), as in the example shown, which are used to generate the S₀ rotation matrix that rotates at a frequency f₀.

As shown in FIG. 6B, the signal IF_{I} may comprise an update component and an f_{I} component. In an example implementation, when update is asserted then the phase generation circuitry updates one of more of f₀-f_{K-1} to be the value of f_{I}.

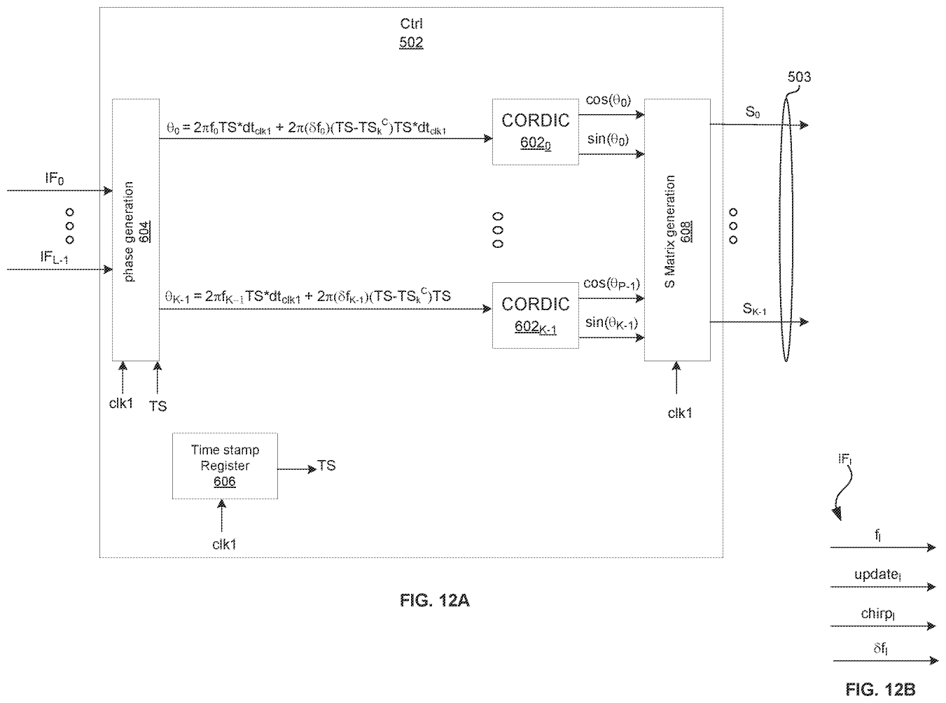

In another example implementation the phase generation circuitry 604 can also generate CORDIC input parameters θ₀-θ_{K-1} that depend on time in a non-linear manner in order, for example, to generate an S-matrix that rotates at a frequency that increases or decreases in time (chirp). A chirp is a signal of the form s(t)=cos(ω(t)t), meaning that the frequency changes with time. A linear chirp can be written as ω(t)=ω₀+αt for some constant α, so that s(t)=cos(ωt+αt²). Note that here this expression assumes starting the chirp at t=0. If a constant frequency is first generated from t=0 to t=t₀ and then the chirp starts, that can be expressed as s(t)=cos(ωt+α(t−t₀)t). The phase of such a signal can be written as θₖ=2πfₖ(TS)(dt_{clk1})+2π(δfₖ)(TS−TS^{C})TS*dt_{clk1}, where δfₖ is the change in frequency per clock cycle of clk1 for the chirp, and TS^{C} is the timestamp at which the chirp is to start (and TS^{C}=TS for timestamps before the chirp starts). An example implementation for a system that generates linear chirps is shown in FIG. 12. Systems in accordance with this disclosure can generate a signal having such a phase without having to do the whole multiplication every time. Instead such systems can increment the phase every cycle. For examples, as described above, in the case of a signal with a fixed frequency (not a chirp), the phase is incremented by θ_{inc}=2πfₖ(dt_{clk1}) every clock cycle. Similarly, in the case of a linear chirp, the phase is incremented by θ_{inc}=2πfₖ(dt_{clk1})+2(δfₖ) (TS−TS^{C}) every cycle and therefore the phase increment, θ_{inc}, itself can be calculated not by multiplication, but by incrementing it by dϕ_{inc}=2π(δfₖ) every clock cycle. In one implementation the phase calculation can be done by the phase generation circuitry 604 as indicated by the pulser via the signal IF (indicating for example whether a chirp should be performed and with what frequency increments). In another implementation the frequency can be provided by the pulser itself via the IF_{I} signal along the chirp. In FIG. 6A, for example, S₀ could be chirped by pulser 302₀ changing the frequency f₀ on each clock cycle so that f=f₀+(δf₀)(TS−TS^{C}). One advantage of this approach is that, because f₀ is calculated by the pulser 302₀ and pulser 302₀ comprises circuitry for performing complex calculations, then complicated chirps such as nonlinear chirps (chirps with different rates of frequency change), can be achieved.

The S-matrix generation circuitry 608 is operable to build the matrices S₀-S_{K-1} from the outputs of the CORDIC circuits 602₀-602_{K-1}. In an example implementation, the S-matrix generation circuit 606 is operable to synchronize changes to the S matrices such that any matrix update occurs on a desired cycle of clock clk1 (which may be determined by the control information IF₀-IF_{L-1}).

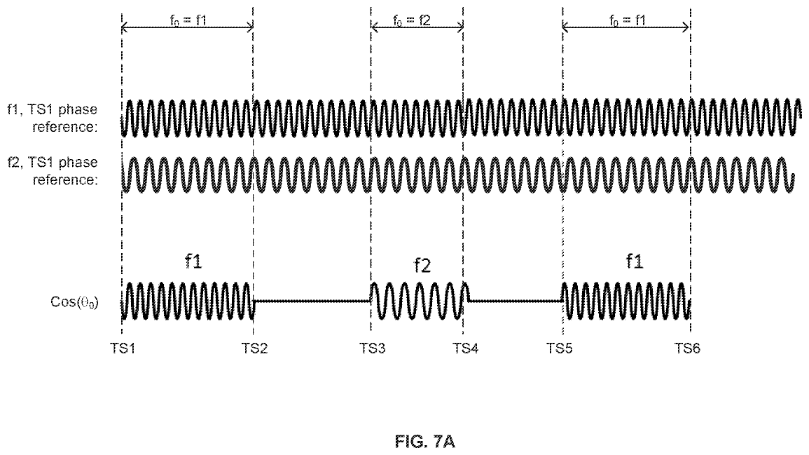

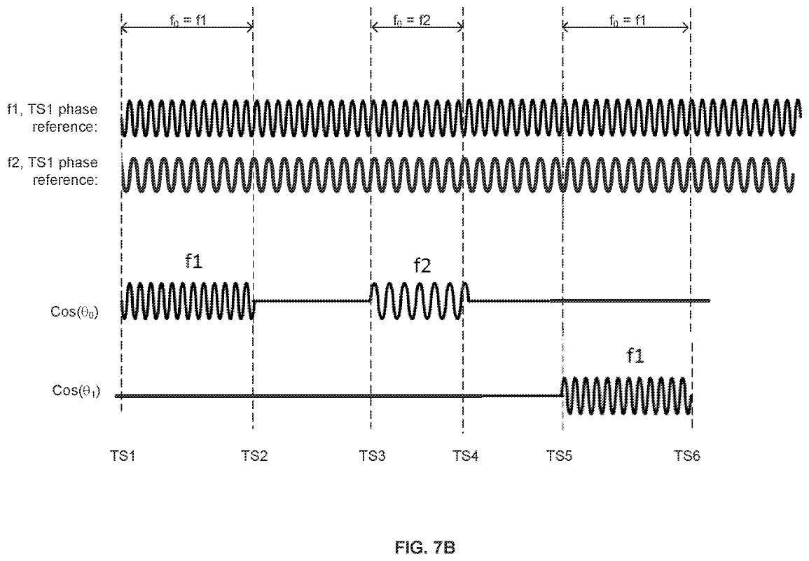

With K CORDIC circuits 602ₖ, the frequency generation circuitry is operable to concurrently generate K S-matrices. In instances that more than K frequencies are needed over the course of a set of instructions, the phase generation circuit 604 is operable to change the input parameter θₖ of one or more of the CORDIC circuits 602₀-602_{K-1} to stop generating one frequency and start generating the K+1^{th} frequency. In some instances, it may be necessary for the new frequency to start at a phase θ that would have been the phase if the new frequency was being generated from the initial reference time (e.g., because the new frequency would be used to address a quantum element that has a resonance at the new frequency and that was coherent since the reference point). In some other instances, it might be necessary to start the new frequency from the phase that the old frequency ended in. The phase generation circuit 604 and timestamp register 606 enable both of these possibilities, as further described below with reference to FIGS. 7A and 7B.

FIGS. 7A and 7B illustrate phase continuity across frequency hops in the frequency generation circuitry of FIGS. 6A and 6B. In FIG. 7, CORDIC 602₀ was arbitrarily selected for illustrating phase continuity, but any of the CORDICs 602₀-602_{N-1} could be used. Similarly, as shown in FIG. 7B, a first one of the CORDICs could have been chosen to generate f1 during the first time interval and a second of the CORDICs could generate f1 during the third time interval, while still providing phase continuity.

From TS=TS1 to TS=TS2, phase generation circuitry 604 generates (based on control signal IF₀) a value of θ₀ such that CORDIC 602₀ generates a pair of phase-quadrature signals at frequency f1 (i.e., θ₀=2π(TS)(dt_{clk1}), where dt_{clk1} is the period of clk1). The two signals can be represented as cos(θ₀) and sin(θ₀). For simplicity of illustration, only the cosine signal is shown in FIGS. 7A and 7B.

From TS=TS3 to TS=TS4, phase generation circuitry 604 generates (based on control signal IF₀) a value of θ₀ such that CORDIC 602₀ generates a pair of phase-quadrature signals at frequency f2. As shown, the phase of cos(θ₀) when it changes frequency to f2 at TS3 is the phase that the signal would have been at if the signal would have been at frequency f2 from the beginning (i.e. from the reference point).

From TS=TS5 to TS=TS6 phase generation circuitry 604 generates (based on control signal IF₀) a value of θ₀ such that CORDIC 602₀ returns to generating a pair of phase-quadrature signals at frequency f1. As shown, the phase of signal 702 when it returns to f1 at TS5 is the phase that the signal would have been at if the frequency never changed and CORDIC 602₀ had been continuously generating f1 since TS1.

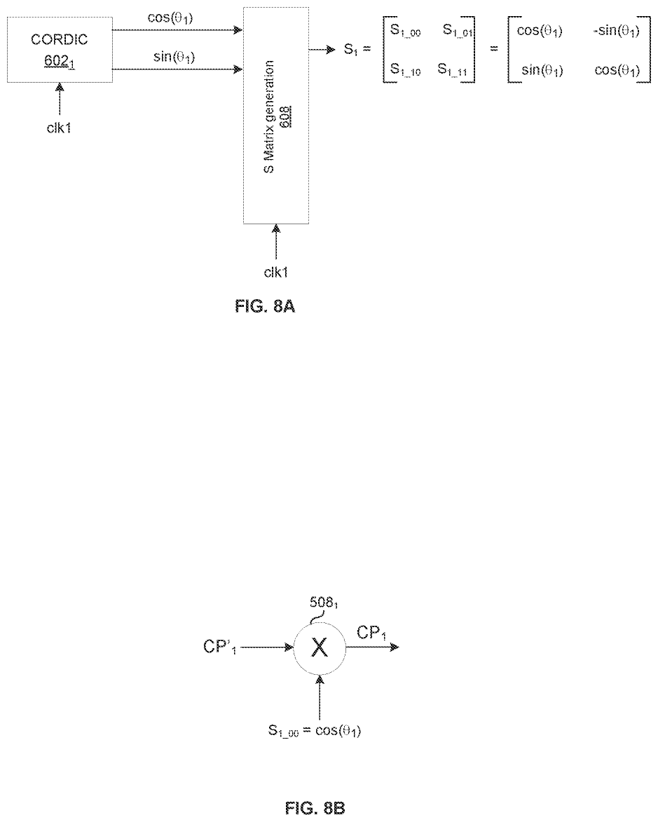

FIG. 8A illustrates an example scenario in which a pulse CP′₁ from pulser 302₁ is to be upconverted to f1. Accordingly, in FIG. 8A, based on control signal(s) IF₁ from pulser 302₁, phase generation circuitry 604 has generated a value of θ₁ that changes every clock cycle according to f1, and S-Matrix generation circuit 608 uses the outputs of CORDIC 602₁ to generate S₁ (which routing circuit 506 of FIG. 5 may then route to pulse modification circuit 508₁). In an example implementation, pulse modification setting 504₁ (which includes matrix S₁, which rotates with frequency f1) is selected from among the pulse modification settings 504₀-504_{K-1} to be used in the pulse modification for this particular pulse. This choice may be based on a pulse modification scheduling algorithm that, for example, seeks to minimize the number of frequency hops that the frequency generation circuitry of 502 has to perform during execution of a set of instructions.

In FIGS. 8B, for clarity of illustration, it is assumed the pulse CP′₁ is an independent pulse (as opposed to a two-pulse pair, as discussed in U.S. patent application Ser. No. 16/247,115, which is hereby incorporated herein by reference in its entirety). Thus, as shown, pulse modification circuit 5083 upconverts the pulse CP′₁ using the first element of the S₁ matrix, S_{1_00}, to generate CP₁. For clarity of illustration the other modifications which may be performed in pulse modification circuitry 508₁ (e.g., multiplication by the F and C matrices described above) are not shown in FIG. 8B.

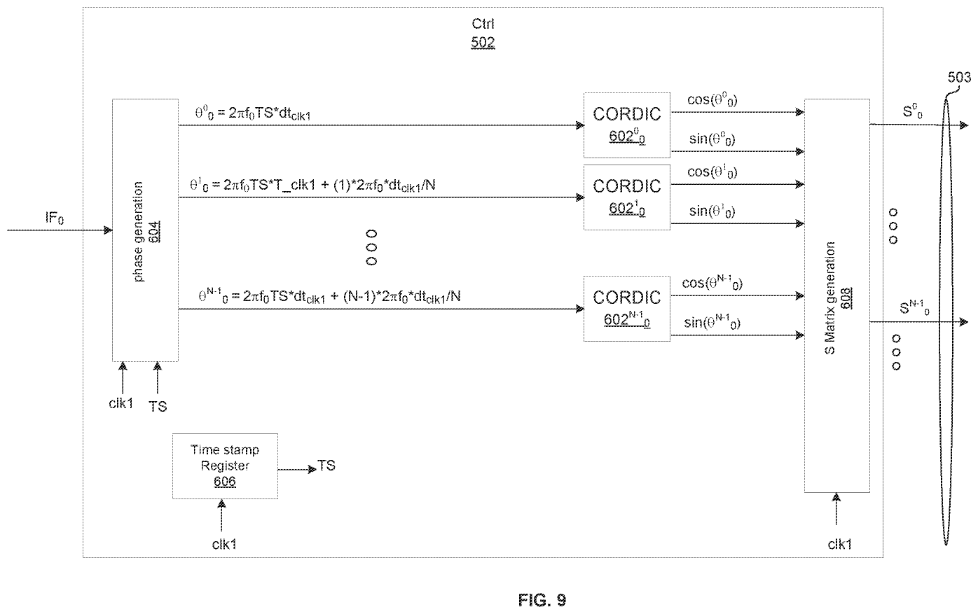

FIG. 9 shows configuration of the frequency generation circuitry of FIGS. 6A and 6B to support sample rates higher than the frequency of the clock, clk1, that clocks the frequency generation circuitry of 502. In FIG. 9, each CORDIC 602ₖ (k an integer between 0 and K−1) of FIG. 6A is replaced by N CORDICs 602ₖ⁰-602ₖ^{N-1} (only 602₀⁰-602₀^{N-1} are shown for simplicity of illustration), and each S matrix Sₖ, is replaced by N S matrices Sₖ⁰-Sₖ^{N-1}.

For the CORDICS 602ₖ⁰-602ₖ^{N-1}, the phase generation circuitry generates N phase parameter values, where each is given by θₖⁿ=2πfₖ(TS)(dt_{clk1})+(n/N)2πfₖ(dt_{clk1}), and fₖ is the frequency instructed by IFₖ, TS is the value of the timestamp register 606, dt_{clk1} is the period of clk1, N is an integer upsampling factor, and n is an integer from 0 to N−1. Thus, the CORDICs 602₀⁰-602₀^{N-1} generate N pairs of signals with each pair having a phase offset of (n/N)22πf₀(dt_{clk1}) relative to the previous pair. The S matrix generation circuitry 608 then generates N S matrices from the N signal pairs.

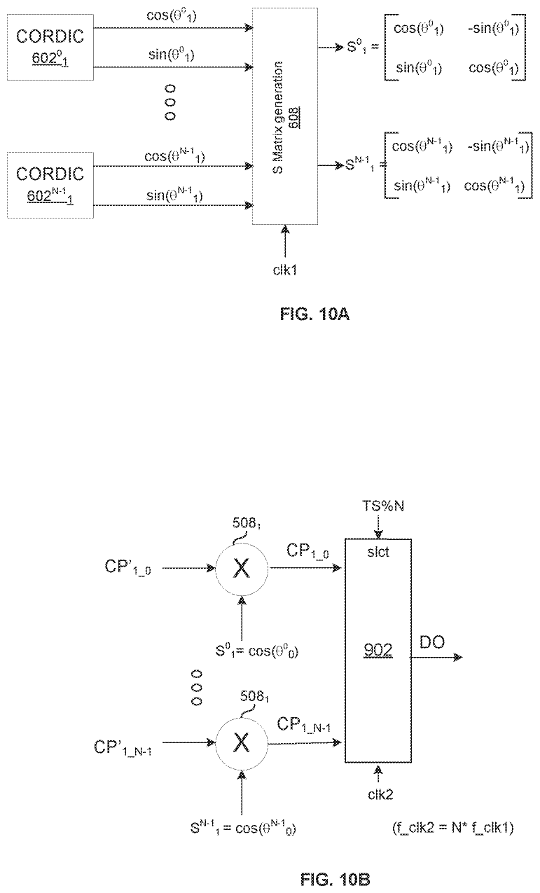

FIGS. 10A and 10B illustrate upconversion of a quantum control pulse in an example implementation of this disclosure. The scenario illustrated in FIGS. 10A and 10B is the same as in FIGS. 8A and 8B, except that CP₁ is required to be at a sample rate that is N times higher than the frequency of clk1. To generate a signal at a sample rate f_clk2=N(f_clk1), N CORDICS are configured to generate N S-matrices S₁⁰-S₁^{N-1} all of which are changing with frequency f1, but each with a different phase offset and the offset of CORDIC 602₁ⁿ is given by (n/N)2πf₀(dt_{clk1})).

As shown in FIG. 10B, the matrices S₁⁰-S₁^{N-1} are routed to pulse modification circuit 508₁, where each of N samples of CP′₁ (CP′_{1_0}-CP′_{1_N-1}) is upconverted using a respective one of the S matrices S₁⁰-S₁^{N-1} to generate the signals CP_{1_0}-CP_{1_N-1}. Then interface circuit 902 which is a part of output manager 360 and is clocked at f_clk2, cyclically selects samples of 903⁰-903^{N-1} to be output as DO₁ (e.g., may select CP_{1_n-1} when TS % N=n) on each cycle of clk2.

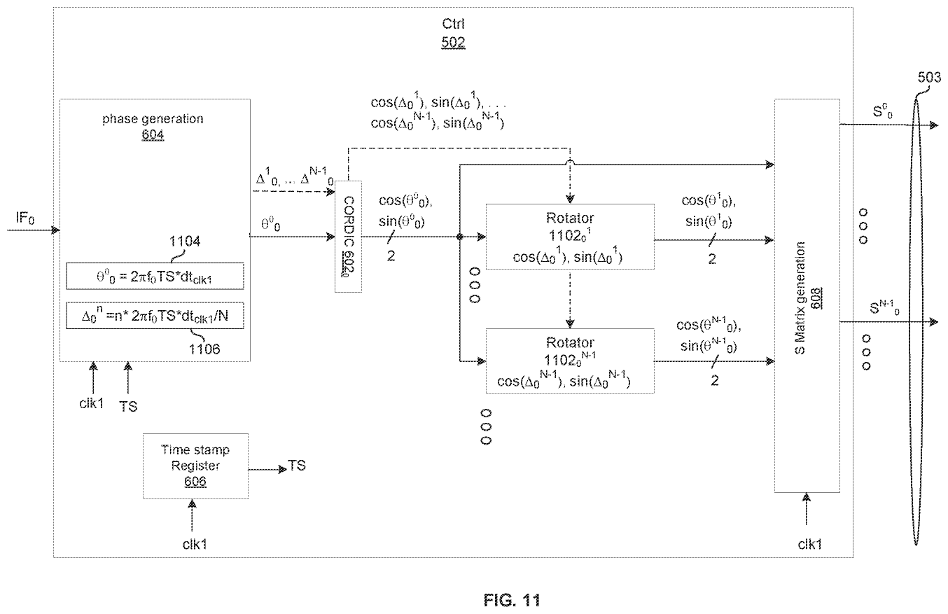

FIG. 11 shows another example configuration of the frequency generation circuitry of FIGS. 6A and 6B to support higher output sample rates. The example implementation in FIG. 11 uses a single CORDIC circuit 602 as compared to N CORDIC circuits in the example implementation of FIG. 9.

In FIG. 11, the phase generation circuitry 604 is operable to generate, for each set of n CORDICs 602ₖ⁰-602ₖ^{N-1} (k an integer from 0 to K), phase parameter θₖ⁰ (e.g., stored in a register 1104) and phase increment parameters Δₖ¹-Δₖ^{N-1} (e.g., stored in a register 1106), where Δₖⁿ=(n/N)2πf₀(dt_{clk1}). For simplicity of illustration only k=0 is shown in FIG. 11.

In operation, a change of the S matrices begins with the phase generation circuitry 604 sequentially outputting each of Δₖ¹-Δₖ^{N-1} to the CORDIC 602ₖ to generate rotation parameters cos(Δₖ¹), sin(Δₖ¹), . . . cos(Δₖ^{N-1}), sin(Δₖ^{N-1}), which are then input, respectively to phase rotator circuits 1102ₖ⁰-1102ₖ^{N-1} (e.g., written to registers of the phase rotator circuits 1102ₖ⁰-1102ₖ^{N-1}.

Once, the rotation parameters have been generated, the phase generation circuit 604ₖ begins outputting θₖ⁰=2πf₀(TS)dt_{clk1} to CORDIC 602ₖ, to generate cos(θₖ⁰) and sin(θₖ⁰) which are then output to the S-matrix generation circuit 608 and to each of the phase rotation circuits 1102ₖ¹-1102ₖ^{N-1}. Each phase rotation circuit 1102₀ⁿ then performs a multiplication of the matrix

$$( \begin{matrix}cos ( {Δ}_{k}^{n} ) & - s in ( {Δ}_{k}^{n} ) \\ sin ( {Δ}_{k}^{n} ) & cos ( {Δ}_{k}^{n} )\end{matrix} )$$

by the vector

$$( \begin{matrix}cos ( {θ}_{k}^{0} ) \\ sin ( {θ}_{k}^{0} )\end{matrix} )$$

to generate cos(θₖⁿ) and sin(θₖⁿ), where θₖⁿ=θₖ⁰+Δₖⁿ.

FIG. 12 shows an example frequency generation circuitry operable to generate chirps. In an example implementation, FIG. 12, the signal IF_{I} comprises two additional signals beyond those shown in FIG. 6B: (1) chirp, which indicates when a chirp is to start (e.g., is high during a chirp and low otherwise); and (2) of which indicates the rate of frequency change for the chirp (a positive value of δfₖ resulting in an upchrip and a negative value of δfₖ resulting in a down chirp). The phase generation circuitry 604 then generates θₖ=2πfₖ(dt_{clk1})+2π(δfₖ)(TS −TSₖ^{C})(TS)dt_{clk1}, where TSₖ^{C} is the clock cycle at which the chirp starts. When a chirp is not in progress (e.g., indicated by chirpₖ being low) then the second term in θₖ is 0, resulting in a constant frequency signal. In an example implementation, δfₖ may be fixed for each chirp. In another example implementation, the phase generation circuitry 604 may reach δfₖ on each clock cycle for which chirp is high and thus the pulser that is generating δfₖ can manipulate δfₖ to achieve non-linear chirps.

In accordance with an example implementation of this disclosure, a quantum controller (e.g., 210) comprising quantum control pulse generation circuitry (e.g., Pulsers 302₀-302_{L-1}), signal generation circuitry (e.g., 602₀-602_{K-1}), and phase parameter generation circuitry (e.g., 604). The quantum control pulse generation circuitry is operable to generate a sequence of two quantum control pulses (e.g., CP_{0,T1}, CP_{0,T2}). The phase parameter generation circuitry is operable to determine, based on an output of the time-tracking circuitry, a first value of a phase parameter (e.g., 2πfₖTS1*dt_{clk1}) to be used for generation of an oscillating signal (e.g., S_{I_00} of FIG. 8B). The signal generation circuitry is operable to, at a first time (e.g., TS1 of FIG. 7A), begin generation of the oscillating signal for modulation of a first of the two quantum control pulses; at a second time (e.g., TS2 of FIG. 7A) after the first time, cease generation of the oscillating signal; and at a third time (e.g., TS5 of FIG. 7A) after the second time, resume generation of the oscillating signal for modulation of the second quantum control pulse, wherein the phase of the oscillating signal is determined by the value of the phase parameter such that the phase of the oscillating signal is as it would have been if the oscillating signal had been generated continuously since the reference time. The output of the time-tracking circuitry (e.g., 606) may correspond to an amount of time lapsed between since a reference time. The time-tracking circuitry may comprise a register (e.g., 606) operable to store a value and increment the value on each cycle of a clock that also clocks the signal generation circuitry (e.g., clk1). The signal generation circuitry may comprises a plurality of signal generation units (e.g., 602₀-602_{K-1}) in parallel. From the first time to the second time, the oscillating signal may be generated by a first of the signal generation units (e.g., 602₀), and from the third time to a fourth time, the oscillating signal is generated by the first of the signal generation units. Alternatively, From the first time to the second time, the oscillating signal may be generated by a first of the signal generation units (e.g., 602₀), and from the third time to a fourth time, the oscillating signal is generated by a second of the signal generation units (e.g., 602₁). The phase parameter generation circuitry may be operable to generate N−1 phase offset values (e.g., (n/N)2πfkT_clk1, for n from 0 to N−1) to be used for generation of the oscillating signal from the first time to the second time, where N is an integer greater than 1. The signal generation circuitry may comprise N signal generation units (e.g., 602₀⁰-602₀^{N-1}). From the first time to the second time, each of N−1 of the signal generation units may generate cosine and sine values based on the first value of the phase parameter and a respective one of the N−1 phase offset values. Each of the N signal generation units may be a CORDIC circuit. The N signal generation units may comprise N−1 phase rotator circuits (e.g., 1102₀¹-1102₀^{N-1}) and only one CORDIC circuit (e.g., 602₀). The quantum controller may comprise matrix generation circuitry (e.g., 608) operable to generate a matrix from the output of the signal generation circuitry. The phase parameter generation circuitry may be operable to determine an amount by which to increase or decrease the phase parameter based on a value (e.g. value of f_{I}) received from the quantum control pulse generation circuitry. The quantum control pulse generation circuitry may be operable to calculate the value during runtime based on a feedback signal (e.g., Al_{I}) from a quantum system (e.g., 218). The phase parameter generation circuitry may be operable to generate the value of the phase parameter based on a control signal (e.g., IF_{I}) from the quantum control pulse generation circuitry. The control signal may indicate a frequency at which the oscillating signal should be generated (e.g. as a value of component f_{I}).

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure. As used herein, the term “based on” means “based at least in part on.” For example, “x based on y” means that “x” is based at least in part on “y” (and may also be based on z, for example).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1-20. (canceled)

21. A system comprising:
signal generation circuitry operable to:
monitor a time-tracking value,
generate a phase parameter according to the time-tracking value, and
generate a signal comprising a desired frequency and the phase parameter.

22. The system of claim 21, wherein the signal generation circuitry comprises a register operable to store the time-tracking value and increment the time-tracking value on each cycle of a clock.

23. The system of claim 21, wherein the signal generation circuitry comprises a hardware gate array.

24. The system of claim 21, wherein the signal generation circuitry comprises a coordinate rotation circuit.

25. The system of claim 21, wherein the signal generation circuitry is operable to alter a plurality of phase parameters over time to during the frequency change.

26. The system of claim 21, wherein a plurality of phase parameters is generated according to a frequency offset signal.

27. The system of claim 26, wherein the signal generation circuitry is operable to adjust the frequency offset signal according to a feedback signal.

28. The system of claim 21, wherein the signal generation circuitry is operable to generate the desired frequency.

29. The system of claim 28, wherein the signal generation circuitry is operable to alter the desired frequency according to a feedback signal.

30. The system of claim 21, wherein each of a plurality of phase parameters has a phase offset relative to others of the phase parameters.

31. A system comprising:
a function generator circuit operable to:
generate a plurality of phase parameters according to time elapsed since a reference time, and
maintain a phase continuity across changes in a desired frequency according to the plurality of phase parameters.

32. The system of claim 31, wherein the function generator circuit comprises a register operable to store a time-tracking value and increment the time-tracking value on each cycle of a clock.

33. The system of claim 31, wherein the function generator circuit is operable to generate an oscillating signal according to the plurality of phase parameters.

34. The system of claim 31, wherein the function generator circuit comprises a coordinate rotation circuit.

35. The system of claim 31, wherein the function generator circuit is operable to alter a phase parameter, of the plurality of phase parameters, over time during changes in a desired frequency.

36. The system of claim 31, wherein the plurality of phase parameters is generated according to a frequency offset signal.

37. The system of claim 36, wherein the function generator circuit is operable to adjust the frequency offset signal according to a feedback signal.

38. The system of claim 31, wherein the function generator circuit is operable to generate the desired frequency.

39. The system of claim 38, wherein the function generator circuit is operable to alter the desired frequency according to a feedback signal.

40. The system of claim 31, wherein the function generator circuit is operable to change the desired frequency from a first value to a second value and then back to the first value.
